(19) United States
(12) Patent Application Publication
(10) Pub. No.: US 2008/0192143 A1
(43) Pub. Date: Aug. 14, 2008

(54) Method and System for Automatic Phase Locking of Analog Inputs

(76) Inventors: Aleksandr Movshovich, Santa Clara, CA (US); Charles Monahan, Mountain View, CA (US)

Correspondence Address: MCANDREWS HELD & MALLOY, LTD, 500 WEST MADISON STREET, SUITE 3400, CHICAGO, IL, 60661, US

(21) Appl. No.: 11/672,755

(22) Filed: Feb. 8, 2007

(51) Int. Cl. H03L 7/00

(52) U.S. Cl. 348/537

(57) ABSTRACT

Methods and systems for automatic phase locking of analog inputs are disclosed. Aspects of one method may include calibrating one of a plurality of video signals. A next phase for a sampling clock may be determined via the calibration, and a phase of the sampling clock may be adjusted to the determined next phase. The samples generated using the sampling clocks may be displayed on a video display, while the samples generated using the calibration clock may not be displayed on a video display.

### CROSS-REFERENCE TO RELATED APPLICATIONS/INCORPORATION BY REFERENCE

[Not Applicable]

### FEDERALLY SPONSORED RESEARCH OR DEVELOPMENT

[Not Applicable]

### MICROFICHE/COPYRIGHT REFERENCE

[Not Applicable]

### FIELD OF THE INVENTION

Certain embodiments of the invention relate to video processing. More specifically, certain embodiments of the invention relate to a method and system for automatic phase locking of analog inputs.

### BACKGROUND OF THE INVENTION

Some conventional video processing systems may be enabled to receive and process an analog video data from video sources. For example, video sources may comprise computers (PCs), mobile video devices (iPod), DVD players, etc. The video information originated from a video source can be delivered to a video monitor in a variety of ways in either analog or digital form, and may utilize a variety of industry standard interfaces. Some of those interfaces were initially designed to carry video data only short distance, for example, from a PC graphics card to a video monitor. Other interfaces, for example, the HDMI interface, may have been designed to provide digital video links for longer distances. A recent trend in video processing systems may signify importance of supporting various industry standard interfaces.

Analog video signals may be converted to digital video signals on the receiver end via analog-to-digital converters (ADC). The ADC may use a sampling clock to facilitate the conversion, and the sampling clock may be synchronized with the incoming data during the system startup. At the time of the synchronization, there may be no valid video information displayed on a monitor, or the video data might not be sufficient for appropriate synchronization and phase alignment of the receiver's ADC clock. The synchronization of the ADC clock process may involve evaluating the input analog signal to phase lock the sampling clock with the input analog signal. This initial synchronization may take time and may occur when no video data is being displayed on a video monitor or other display device.

However, if there was not enough video data for the initial synchronization, or if re-alignment of the ADC clock may be desired after the initialization process, the resulting synchronization may occur during normal video system operation. Re-synchronization may be desired to correct phase errors in ADC clocking, and/or to correct the sampling clock drift over time as well as instability of the analog signal due to time delay versus the sampling clock. This re-synchronization may be manually initiated by, for example, the video monitor viewer if the viewer determines that the video signal needs to be re-synchronized. For example, the video may comprise blurry images with primary colors misaligned relative to each other. In such cases, during the re-synchronization, the video monitor user may notice the phase sweep artifacts since re-synchronization may occur while the video data is being displayed on the video monitor.

Further limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

A system and/or method for automatic phase locking of analog inputs, substantially as shown in and/or described in connection with at least one of the figures, as set forth more completely in the claims.

Various advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a block diagram of an exemplary video processing system, which may be utilized in connection with an embodiment of the invention.

FIG. 2 is an exemplary illustration of a pixel in an analog video signal.

FIG. 3 is a block diagram illustrating an exemplary phase locked loop, which may be utilized in connection with an embodiment of the invention.

FIG. 4 is a block diagram illustrating sampling of analog signals.

FIG. 5A is a block diagram illustrating exemplary automatic sampling of analog signals, in accordance with an embodiment of the invention.

FIG. 5B is a block diagram illustrating exemplary sampling of a pixel, in accordance with an embodiment of the invention.

FIG. 6 is an exemplary flow diagram for automatic phase locking to analog input signals, in accordance with an embodiment of the invention.

### DETAILED DESCRIPTION OF THE INVENTION

Certain embodiments of the invention may be found in a method and system for automatic phase locking of analog inputs. Aspects of the method may comprise calibrating one of a plurality of video signals for phase lock between the video signal and a calibration clock used to sample that video signal. A next phase for the calibration clock may be determined via the calibration. A sampling clock that may correspond to the calibrated video signal may be adjusted to the determined next phase. The next phase for the sampling clock may be one of a plurality of phases that may be used for the sampling clock. The samples generated using the sampling clock may be displayed on a video display, while the samples generated using the calibration clock may not be displayed on a video display.

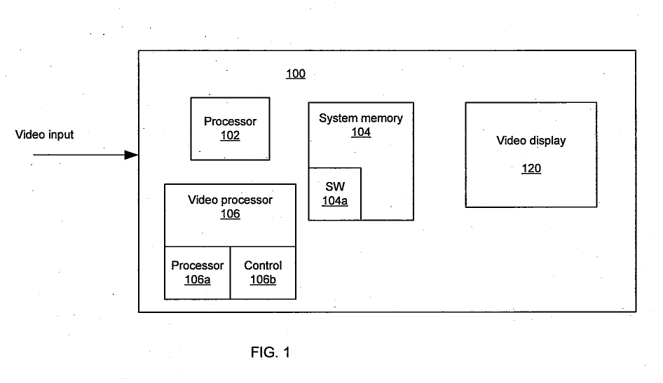

FIG. 1 is a block diagram of an exemplary wireless system, which may be Utilized in connection with an embodiment of the invention. Referring to FIG. 1, a video monitor 100 that may comprise a video display 120 may be shown. The video monitor 100 may or may not comprise a television tuner. For example, the video monitor 100 may be a HDTV set. The video monitor 100 may comprise a processor 102, system memory 104, and a video processor block 106. The video processor block 106 may comprise a processor 106a and control block 106b. The processor 102 may be, for example, a main processor of a television motherboard. The system memory 104 may comprise volatile memory, such as, for example, RAM and non-volatile memory, such as, for example, ROM and/or hard drive. The system memory may also comprise software 104a that may be used, for example, to process the analog video signals.

The video processor block 106 may comprise suitable logic, circuitry, and/or code that may enable processing video input for storage in the system memory 104, and/or displaying video on the video display 120. The video processor block 106 may also comprise, for example, a processor 106a, which may be dedicated to processing video signals. Notwithstanding, the invention is not limited in this regard, and a dedicated or non-dedicated processor may be utilized to process the video signals. The processor 106a may also be utilized to process video signals. The processor 106a may have access to memory, such as the system memory 104 and/or local memory (not shown). The control block 106b may comprise suitable logic, circuitry, and/or code that may enable processing of video signals.

In operation, the video monitor 100 may receive analog video data from, for example, a PC (not shown). Various portions of the video monitor 100 may control synchronization of a sampling clock to the analog video data. For example, different delays may be provided to a sampling clock, and this may be referred to as a phase sweep. The phase sweep may involve, for example, at least portions of the video processor block 106, such as the processor 106a and/or control block 106b. The analog video data may be converted to sampled digital data for storage in the system memory 104 for display at a later time and/or for display on the video display 120. For example, the sampled digital data may be stored for a digital video recorder functionality.

When an analog video signal is first received from a source such as a PC, a phase sweep may occur prior to displaying the video images on the video display 120. The phase sweep may, for example, provide different phases, or delays, to a sampling clock. This may allow pixels to be sampled at different times with respect to start of a pixel period. Accordingly, an appropriate phase for a sampling clock may be determined from the phase sweep. This may allow more accurate samples of digital signals to be displayed. The various functionalities may be software controlled, for example, via the software 104a and/or via various hardware circuitry in the video monitor 100.

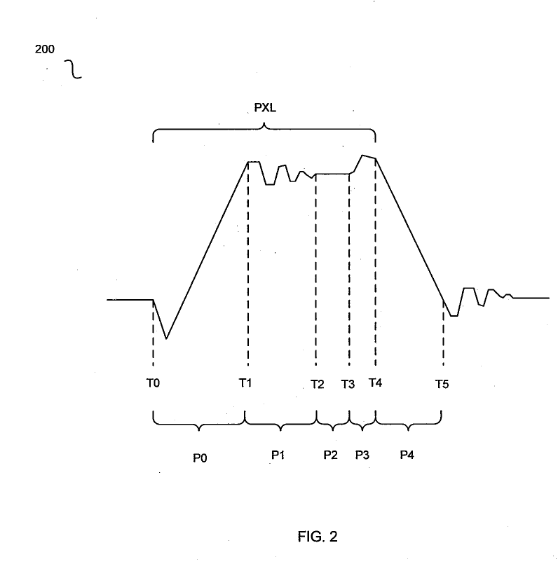

FIG. 2 is an exemplary illustration of a pixel in an analog video signal. Referring to FIG. 2, there is shown an analog video signal 200. The analog video signal 200 may comprise a series of pixels, where a pixel may change signal levels from one level to another level. A pixel period PXL may comprise, for example, the periods P0, P1, P2, and P3, where the pixel period PXL may start, for example, at the time instance T0 and end at the time instance T4.

Accordingly, a video signal level may change from a previous pixel to a present pixel during the period P0. The period P0, which may be approximately from the time instance T0 to the time instance T1, may be a transition time from a signal level of a previous pixel to the signal level of the present pixel. Sampling the analog video signal 200 during this period may not be desired since the analog video signal 200 may have not transitioned to the final signal level for the present pixel. Similarly, the period P4, which may be approximately from the time instance T4 to the time instance T5, may be a transition time from a signal level of the present pixel to the signal level of a next pixel. The period P4 may also not be useful for sampling a pixel signal level.

The period P1, which may be approximately a period of time from the time instance T1 to the time instance T2, may be a period of time during which the analog video signal 200 may settle once the signal level has transitioned for the present pixel. The settling time may be needed due to, for example, signal ringing if the analog video signal is not appropriately terminated. Sampling the analog video signal 200 during this period may give an inaccurate sample since the analog video signal 200 may have not settled to the final signal level for the present pixel.

The period P2, which may be approximately a period of time from the time instance T2 to the time instance T3, may be a period of time during which the analog video signal 200 may have settled to the appropriate signal level for the present pixel. The analog video signal 200 may be sampled during this period to generate an accurate digital sample for the signal level of the present pixel.

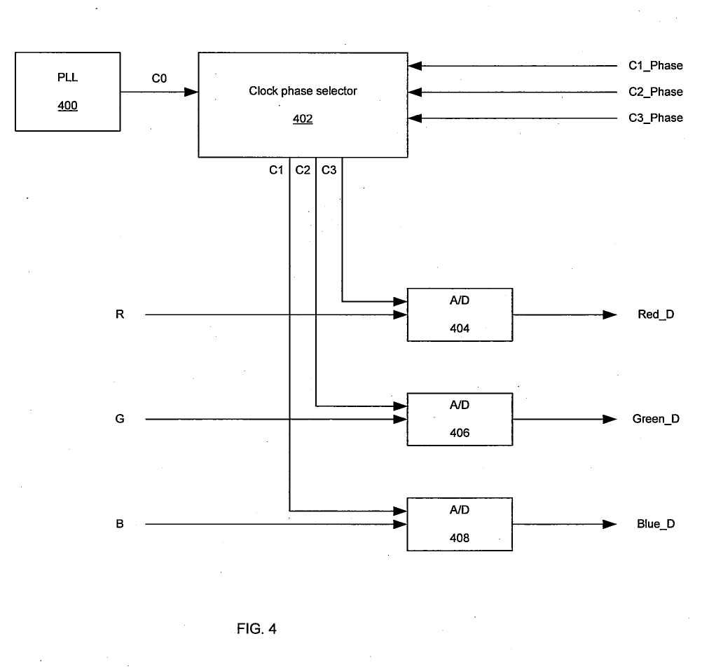

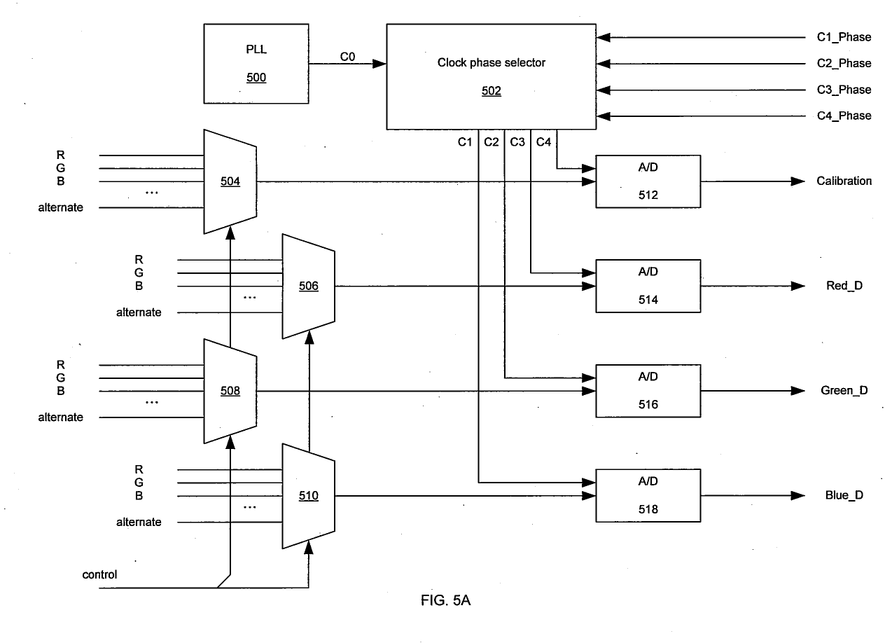

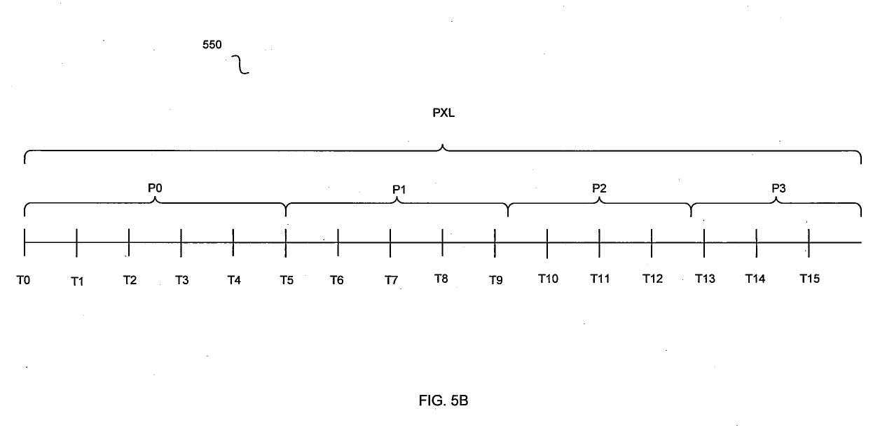

Accordingly, a period in which to accurately sample a pixel may be limited to a small portion of a pixel period. Therefore, a sampling clock may need to be synchronized with analog video signals in order to be able to accurately sample the input signals. A method for determining accuracy of a sample of an input signal may be design and/or implementation dependent. Digitally sampling an input signal is discussed in more detail with respect to FIGS. 4, 5A, and 5B.

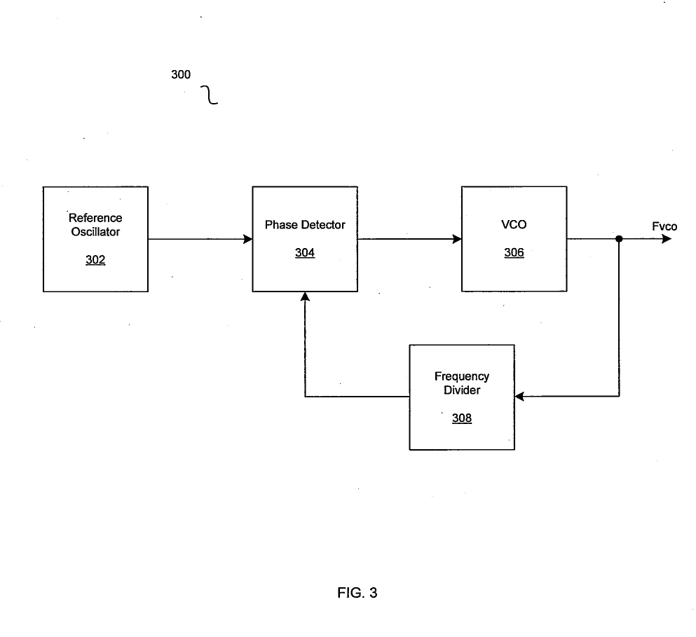

FIG. 3 is a block diagram illustrating an exemplary phase locked loop, which may be utilized in connection with an embodiment of the invention. Referring to FIG. 3, there is shown a phase locked loop (PLL) 300 comprising a reference oscillator 302, a phase detector 304, a voltage controlled oscillator (VCO) 306, and a frequency divider 308.

The reference oscillator 304 may comprise suitable logic and/or circuitry that may be adapted to generate a signal of a fixed frequency. The signal may be utilized as a reference signal for a phased lock loop circuit. This signal may be a low frequency signal on the order of, for example, megahertz or tens of megahertz. The phase detector 304 may comprise suitable logic and/or circuitry that may be adapted to compare two signals and generate an output voltage that may indicate whether the two signals have the same frequency, or whether the frequency of one signal may be larger than the frequency of the other signal.

The voltage controlled oscillator 306 may comprise suitable logic and/or circuitry that may be adapted to generate a signal that may vary in frequency according to an input control voltage. The input control voltage may be communicated by the phase detector 304. The voltage controlled oscillator 306 may be utilized to generate RF carrier signals that may be utilized to upconvert baseband or IF signals to RF signals.

The frequency divider 308 may comprise suitable logic and/or circuitry that may be adapted to reduce the frequency of an input signal, for example, the output signal, F_{vco}, from the voltage controlled oscillator 306, where the reduction may be by an integer factor or a non-integer factor. The output of the frequency divider 308 may be communicated to the phase detector 304. The phase detector 304 may compare the output of the frequency divider 308 and the output of the reference oscillator 302. The phase detector 304 may generate a suitable voltage to communicate to the voltage controlled oscillator 306, which may indicate whether to increase the frequency of the output signal, F_{vco}, decrease the frequency of the output signal, F_{vco}, or keep the frequency of the output signal, F_{vco}, at the same frequency.

In operation, the frequency divider 308 may divide the output signal, F_{vco}, from the voltage controlled oscillator 306 to generate a signal that may be the same frequency as the reference signal generated by the reference oscillator 100. However, if the output signal, F_{vco}, is not quite a desired multiple of the reference signal generated by the reference oscillator 302, or if it is an incorrect multiple of the reference signal generated by the reference oscillator 302, the phase detector 304 may generate a control input voltage. The control input voltage may be communicated to the voltage controlled oscillator 306 to drive the frequency of the output signal, F_{vco}, to the desired frequency value.

FIG. 4 is a block diagram illustrating sampling of analog signals. Referring to FIG. 4, there is shown a PLL 400, a cock phase selector 402, and analog-to-digital converters (ADCs) 404, 406, and 408, in the video processor block 106. The PLL 400 may be similar to the PLL 302. Each of the ADCs 404, 406, and 408 may receive, for example, an analog input signal such as the R, G, B analog video signal, respectively.

In operation, each of the R, G, and B signals may be received by the ADCs 404, 406, and 408, respectively. A clock signal C1, C2, and C3, respectively, for each of the ADCs 404, 406, and 408 may be provided by the clock phase generator 402. The clock phase generator 402 may have as inputs signals C1_Phase, C2_Phase, and C3_Phase. The signals C1_Phase, C2_Phase, and C3_Phase may be used to provide appropriate phase information to the clock signals C1, C2, and C3, respectively, with respect to the clock signal C0 from the PLL 400. Accordingly, each clock signal C1, C2, and C3 may have a frequency that may be similar to the clock signal C0 from the PLL 400. The phase of the clock signals C1, C2, and C3 may be, for example, a delay with respect to the clock signal C0. The signals C1_Phase, C2_Phase, and C3_Phase may be generated by, for example, the control block 106b and/or a processor such as the processor 102 or 106a.

In an exemplary embodiment of the invention, the clock signal C1 may be used to sample the analog video signal R at various sample points. The sampling point may be changed as a phase of the clock signal C1 is changed. The phase of C1 may be indicated by the input signal C1_Phase. The clock signal C1 may have a similar period as a pixel. The phase of the clock signal C1, which may be changed by delaying of the clock signal C1 with respect to the PLL output clock signal C0, may be shifted from, for example, 0 to 360 degrees by a phase increment, which may be a delay interval for a clock signal. The phase increment may be design and/or implementation dependent. Accordingly, the pixel period PXL from the time instance T0 to the time instance T4 may be sampled at various points for successive pixels during the phase sweep for an input signal. Similarly, the analog video signals G and B may also be sampled.

The phase of the clock signal C1 may be adjusted, for example, in increments of 1/16^{th} of the pixel period. Accordingly, the R signal may be sampled at one of 16 different sample points. The output of the ADC 404 may be, for example, stored in the system memory 104 and/or communicated to a processor, such as, for example, the processor 102 or the processor 106a, and/or the control block 106b. The processor may then determine a next sampling clock phase, which may determine a sampling point for the pixels, based on the various samples of the signal R. For example, with respect to the video signal 200, a next phase may be determined that allows sampling to occur between the time instances T2 and T3. Accordingly, a next phase may be one of a plurality of phases that may allow sampling between the time instances T2 and T3. An algorithm for determining a next phase may be design and/or implementation dependent. For example, an embodiment of the invention may use as a next phase a phase that may result in a sample that may be determined to be as good or better than samples resulting from using a present phase. Similarly, the analog signals G and B may also be phase swept to determine a next clock phase for sampling each of those signals.

FIG. 5A is a block diagram illustrating exemplary automatic sampling of analog signals, in accordance with an embodiment of the invention. Referring to FIG. 5A, there is shown a PLL 500, a clock phase selector 502, multiplexers 504, 506, 508, and 510, and analog-to-digital converters (ADCs) 512, 514, 516, and 518, in the video processor block 106. The PLL 500 may be similar to the PLL 302. The functionality of the clock phase selector 502 may be similar to the functionality of the clock phase selector 402, however, four clock signals C1, C2, C3, and C4 may be generated from the clock signal C0 from the PLL 500. The phases may be indicated by four signals C1_Phase, C2_Phase, C3_Phase, and C4_Phase. The multiplexers 504, 506, 508, and 510 may be controlled by, for example, a processor such as the processor 102 or 106a, and/or the control block 106b, as to which input signal for each multiplexer may be selected for output.

In operation, the video processor block 106 may receive a plurality of input signals, such as, for example, the analog video signals R, G, and B. The video processor block 106 may also receive other analog video signals. The other analog video signals may comprise, for example, composite video signal and/or S-video signals. The multiplexer 506 may be communicated control signals that enable selection of the analog video signal R, for example. The multiplexers 508 and 510 may utilize similarly communicated control signals to enable selection of the analog video signals G and B, respectively. Accordingly, the ADCs 514, 516, and 518 may receive the analog video signals R, G, and B, respectively.

The ADCs 514, 516, and 518 may receive the clock signals C3, C2, and C1, respectively, from the clock phase selector 502 for use in sampling the analog video signals. The ADCs 514, 516, and 518 may use the clock signals C3, C2, and C1, respectively, to sample a respective input signal, such as, for example, the analog video signals R, G, and B from the multiplexers 506, 508, and 510. While the frequencies of the clock signals C1, C2 and C3 may be similar, the phases of the clock signals C1, C2 and C3 may be different. The phases of clock signals may be different, for example, if one clock signal is delayed with respect to another.

The phase of a clock signal may be adjusted by the clock phase selector 502. The clock phase adjuster 502 may receive phase information for a clock. The phase information may be communicated by, for example, a processor such as the processor 102 and/or the processor 106a, and/or the control block 106b. The phase information may be communicated by the signals C1_Phase, C2_Phase, C3_Phase, and C4_Phase. The signal C1_Phase may, for example, indicate a number of delay intervals by which to delay the clock signal C1 with respect to, for example, a clock signal that may be communicated by the PLL 500. For example, a delay interval may be 1/16^{th} of a period of a pixel period, and the number of delay intervals may range from zero to 15. The delay interval and/or the number of delay intervals that a clock signal may be delayed by may be design and/or implementation dependent.

Accordingly, a clock signal may be used to sample a signal at different sampling points of the input signal by using a different delay interval at different times. For example, the analog video signal R may comprise sequential pixels, where a pixel period may have a time period of 16X. By using a delay interval of X, the sampling clock C3 may sample a pixel at a particular point in time with respect to a start of a pixel period. Accordingly, each pixel may be sampled at one of 16 different times with respect to start of a pixel period. This is illustrated with respect to FIG. 5C.

The outputs of the ADCs 514, 516, and 518 may also be displayed on the video display 120. The outputs of the ADCs 514, 516, and 518 may also be stored in memory, such as, for example, the system memory 104, and/or communicated to the processor 102 and/or 106a, and/or the control block 106b. The phase adjustment for the sampling clock signals for the ADCs 514, 516 and 518 may be determined by processing signals from, for example, the ADC 512. The ADC 512 may sample a signal from the multiplexer 504. The multiplexer 504 may be enabled to select an input signal to communicate to the ADC 512. The input signal selected may be, for example, an input signal selected by one of the multiplexers 506, 508, or 510. Accordingly, the ADC 462 may execute a phase sweep for a signal without affecting video displayed from the outputs of the ADCs 514, 516, and 518.

Phase sweeps for each of the signals communicated to the ADCs 514, 516, and 518 may be executed, for example, in a continuous manner where the signal for the ADC 514 may be selected, then the signal for the ADC 516, then the signal for the ADC 518, then back to the signal for the ADC 514, and so on. An amount of time allocated for phase sweeping of each signal may be design and/or implementation dependent. Different algorithms for phase sweeps may require different time periods to complete. Additionally, the phase sweeps may not be executed consecutively. For example, there may be a period of time between determination of a phase delay for one signal and start of phase sweep for another signal. For example, a processing time for evaluating various samples may be taken into account. The delay between phase sweeps may, for example, also depend on stability of analog video signals and/or stability of the clock signal C0 from the PLL 500.

By executing a phase sweep for a signal, for example, the analog video signal R, using the multiplexer 504 and the ADC 512, a processor may be able to determine a number of delay intervals to be used to generate samples. The determined number of delay intervals, which may or may not be the same as a present number of delay intervals, may then be communicated to the clock phase selector 502 via the C3_Phase signal, and the phase of the clock signal C3 may be appropriately adjusted. Similarly, the multiplexer 504 may select the analog video signal G and B in turn, and may determine next phases for the sampling clocks C2 and C1, respectively, used for these signals. The phases of the sampling clocks C2 and C1 may then be adjusted appropriately.

FIG. 5B is a block diagram illustrating exemplary sampling of a pixel, in accordance with an embodiment of the invention. Referring to FIG. 5B, there is shown a diagram 500, where the diagram may be with respect to a pixel, for example, of the analog video signal 200 with a pixel period of PXL. There is also shown the periods P0, P1, P2, and P3 that may correspond to the periods P0, P1, P2, and P3 described with respect to FIG. 2. The time instances T0, T1, . . . , T14, and T15 may be various times instances to which a phase of a sampling clock may be adjusted. For example, the period PXL may be 16X. Accordingly, a delay of zero by the clock phase adjuster 502 may generate a clock signal that may sample at time instance T0. A delay of X may generate a clock signal that may sample at time instance T1. Similarly, each additional delay of X may adjust the phase of the clock signal to sample at time instances T2, . . . , T14, or T15, respectively.

As described with respect to FIG. 2, sampling the pixel 500 during the periods P0, P1, or P3 may generate an inaccurate sample. Accordingly, a phase sweep for an analog Video signal that the pixel 500 may be a part of, may determine that phase adjustment of the clock to enable sampling of the pixel 500 at the time instances T10, T11, or T12 may be desirable. An algorithm for determining an appropriate phase adjustment for a sampling clock signal used for sampling a signal may be design and/or implementation dependent.

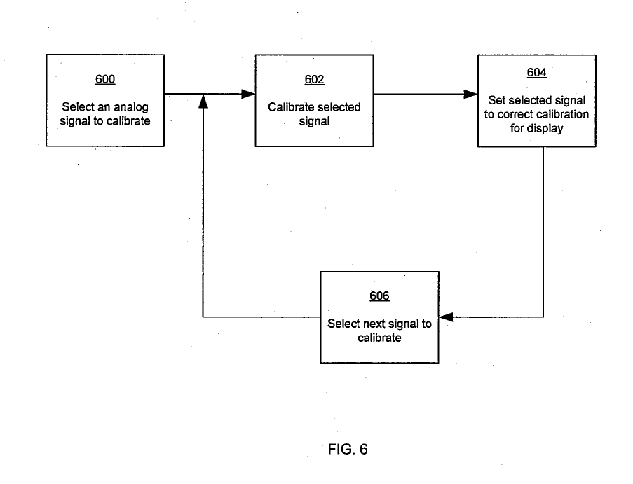

FIG. 6 is an exemplary flow diagram for automatic phase locking to analog input signals, in accordance with an embodiment of the invention. Referring to FIG. 6, there is shown steps 600 to 606. In step 600, an analog video signal may be selected for a phase sweep. For example, the multiplexer 504 may select the analog video signal R. In step 602, the phase sweep for the selected signal may determine a desired phase for the sampling clock for the analog video signal R. The determined next phase for the clock signal may be the same as the present phase for the sampling clock signal or different from the present phase.

In step 602, a processor such as the processor 102 or 106a, and/or the control block 106b may calibrate a sampling clock signal, for example. Various clock phases for the calibrating clock signal C4 may be communicated to the clock phase adjuster 502 via the signal C4_Phase. The clock phase adjuster 502 may appropriately adjust the phase of the calibrating clock signal C4 as each phase is received for the calibrating clock signal C4. Accordingly, the ADC 512 may sample pixels of the analog video signal R at various points of a pixel. The samples may be stored in memory, for example, the system memory 104. The processor 102, for example, may then process the samples generated by the ADC 512 to determine a next clock phase.

In step 604, the next clock phase may then be communicated to the appropriate ADC that may be sampling the analog video signal. For example, since the ADC 512 may be sampling the analog video signal R, the desired clock phase may be communicated to the clock phase selector 502 via the signal C3_Phase. The phase of the sampling clock signal C3 may be adjusted accordingly so that the analog video signal R may be sampled at a desired portion of each pixel. In this manner, the analog video signal may be phase locked with the sampling clock signal used to sample that analog video signal. In step 606, a next analog video signal may be selected for calibration via a phase sweep. The next step after step 606 may be step 602. In this manner, the multiplexer 504 and the ADC 512 may be used to monitor the phase lock of each sampling clock with its corresponding analog video signal. Accordingly, the phase for the sampling clock may be adjusted automatically.

In accordance with an embodiment of the invention, aspects of an exemplary system may comprise the clock phase selector that may generate a calibration clock signal C4 and sampling clock signals C1, C2, and C3, where the phases of the calibration clock signal C4 and the sampling clock signals C1, C2, and C3 may be adjusted. The phase adjustment for each clock signal may be communicated via control signals, for example, the signals C1_Phase, C2_Phase, C3_Phase, and C4_Phase. These control signals may be communicated by, for example, the processor 102, 106a, and/or the control block 106b. The calibration clock signal C4 may be used to calibrate one of a plurality of analog video signals at a time. The calibration clock signal C4 may be used by the ADC 512 to generate pixel samples by phase sweeping the analog video signal input to the ADC 512. The pixel samples may be processed by, for example, the processor 102, 106a, and/or the control block 106b.

The processing of the samples may result in a determination of a next phase to be used for the sampling clock. The next phase may be determined after the phase sweeping is complete, or while the phase sweeping is taking place. The particular method of determining the next phase may be design and/or implementation dependent. The next phase may be communicated to the sampling clock that may be used for the signal that was calibrated. For example, if the calibration was for the analog video signal R, the next phase may be communicated to the clock phase selector 502 via the appropriate control signal C3_Phase, and the sampling clock C3 may be adjusted to the next phase determined during the calibration for the analog video signal R. The samples generated by the ADC 512 via the calibration clock signal C4 may not be displayed on a video display. One calibration ADC may be shared by a plurality of input analog video signals, or there may be one calibration ADC for each input analog video signal. For example, the ADC 512 may be shared by all the input analog video signals.

While an embodiment of the invention may have been described using a single calibrating ADC, for example, the ADC 512, the invention need not be so limited. For example, another embodiment of the invention may comprise a calibrating ADC for monitoring each analog video signal. Accordingly, with respect to FIG. 4, there may be an ADC for each of the ADCS 404, 406, and 408. In this manner, each of the ADCs 404, 406, and 408 may have a dedicated calibrating ADC. Other embodiments of the invention may use a different number of ADCs for the analog video signals.

Also, while an embodiment of the invention may have described an appropriate phase being determined after a phase sweep, the invention need not be so limited. For example, an algorithm may allow processing sampled data as they are generated, rather than accessing the samples from memory. Accordingly, an algorithm may decide upon a next delay to be used for a sampling clock for an analog video signal before the phase sweep for that analog video signal is completed. In that event, the phase sweep for the present analog video signal may be terminated before all the different delay intervals may have been communicated to the calibrating clock.

While the phase sweep may have been described with respect to the video signals, a phase sweep may also be thought of as occurring for the calibration clock. That is, varying the phase of the calibration clock may be a phase sweep for the calibration clock, and a selected phase of the calibration clock may be used for a sampling clock.

Another embodiment of the invention may provide a machine-readable storage, having stored thereon, a computer program having at least one code section executable by a machine, thereby causing the machine to perform the steps as described above for automatic phase locking of analog inputs.

Accordingly, the present invention may be realized in hardware, software, or a combination of hardware and software. The present invention may be realized in a centralized fashion in at least one computer system, or in a distributed fashion where different elements are spread across several interconnected computer systems. Any kind of computer system or other apparatus adapted for carrying out the methods described herein is suited. A typical combination of hardware and software may be a general-purpose computer system with a computer program that, when being loaded and executed, controls the computer system such that it carries out the methods described herein.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will comprise all embodiments falling within the scope of the appended claims.

What is claimed is:

1. A method for processing signals, the method comprising:
generating a calibration clock with a phase different from a phase of a sampling clock;
calibrating one of a plurality of video signals by using said calibration clock to sample said one of said plurality of video signals;
determining via said calibration, a next phase for said sampling clock that corresponds with said one of said plurality of video signals being calibrated; and
adjusting a phase of said corresponding sampling clock for said one of said plurality of video signals to said determined next phase.

2. The method according to claim 1, wherein samples generated, using said calibration clock, for said one of said plurality of video signals being calibrated are not displayed on a video display.

3. The method according to claim 1, comprising phase sweeping said one of said plurality of video signals during said calibrating.

4. The method according to claim 3, wherein said next phase is determined after said phase sweeping of said one of said plurality of video signals.

5. The method according to claim 3, wherein said next phase is determined during said phase sweeping of said one of said plurality of video signals.

6. The method according to claim 1, comprising phase sweeping said calibration clock during said calibrating.

7. The method according to claim 6, wherein said next phase is determined after said phase sweeping of said calibration clock.

8. The method according to claim 6, wherein said next phase is determined during said phase sweeping of said calibration clock.

9. The method according to claim 1, wherein a single ADC is used for said calibrating of said plurality of video signals.

10. The method according to claim 1, wherein a plurality of ADCs is used for said calibrating of said plurality of video signals.

11. A machine-readable storage having stored thereon, a computer program having at least one code section for processing signals, the at least one code section being executable by a machine for causing the machine to perform steps comprising:
generating a calibration clock with a phase different from a phase of a sampling clock;
calibrating one of a plurality of video signals by using said calibration clock to sample said one of said plurality of video signals;
determining via said calibration, a next phase for said sampling clock that corresponds with said one of said plurality of video signals being calibrated; and
adjusting a phase of said corresponding sampling clock for said one of said plurality of video signals to said determined next phase.

12. The machine-readable storage according to claim 11, wherein samples generated, using said calibration clock, for said one of said plurality of video signals being calibrated are not displayed on a video display.

13. The machine-readable storage according to claim 11, wherein the at least one code section comprises code for phase sweeping said one of said plurality of video signals during said calibrating.

14. The machine-readable storage according to claim 13, wherein said next phase is determined after said phase sweeping of said one of said plurality of video signals.

15. The machine-readable storage according to claim 13, wherein said next phase is determined during said phase sweeping of said one of said plurality of video signals.

16. The machine-readable storage according to claim 11, wherein the at least one code section comprises code for phase sweeping said calibrating clock during said calibrating.

17. The machine-readable storage according to claim 16, wherein said next phase is determined after said phase sweeping of said calibrating clock.

18. The machine-readable storage according to claim 16, wherein said next phase is determined during said phase sweeping of said calibrating clock.

19. The machine-readable storage according to claim 11, wherein a same ADC is used for said calibrating of said plurality of video signals.

20. The machine-readable storage according to claim 11, wherein a plurality of ADCs is used for said calibrating of said plurality of video signals.

21. A system for processing signals, the system comprising:
calibrating circuitry that enables generation of a calibration clock with a phase different from a phase of a sampling clock, wherein said calibrating circuitry enables calibrating of one of a plurality of video signals by using said calibration clock to sample said one of said plurality of video signals;
processing circuitry that enables determining via said calibrating, a next phase for said sampling clock that corresponds with said one of said plurality of video signals being calibrated; and
a clock phase selector that enables adjusting of a phase of said corresponding sampling clock for said one of said plurality of video signals to said determined next phase.

22. The system according to claim 21, wherein samples generated, using said calibration clock, for said one of said plurality of video signals being calibrated are not displayed on a video display.

23. The system according to claim 21, wherein said one of said plurality of video signals is phase swept during said calibrating.

24. The system according to claim 23, wherein said next phase is determined after phase sweeping of said one of said plurality of video signals.

25. The system according to claim 23, wherein said next phase is determined during phase sweeping of said one of said plurality of video signals.

26. The system according to claim 21, wherein said calibration clock is phase swept during said calibrating.

27. The system according to claim 26, wherein said next phase is determined after phase sweeping of said calibration clock.

28. The system according to claim 26, wherein said next phase is determined during phase sweeping of said calibration clock.

29. The system according to claim 21, wherein a single ADC is used for said calibrating of said plurality of video signals.

30. The system according to claim 21, wherein a plurality of ADCs is used for said calibrating of said plurality of video signals.
